(19) United States
(12) Patent Application Publication
(10) Pub. No.: US 2021/0036486 A1
(43) Pub. Date: Feb. 4, 2021

(54) Laser Chip Design

(71) Applicant: HUAWEI TECHNOLOGIES CO., LTD., Shenzhen (CN)

(72) Inventors: Ning Cheng, Basking Ridge, NJ (US); Xiang Liu, Marlboro, NJ (US); Frank Effenberger, Frisco, TX (US)

(21) Appl. No.: 17/074,334

(22) Filed: Oct. 19, 2020

Related U.S. Application Data
(63) Continuation of application No. PCT/CN2019/089144, filed on May 30, 2019.
(60) Provisional application No. 62/678,091, filed on May 30, 2018.
(60) Provisional application No. 62/821,082, filed on Mar. 20, 2019.

(51) Int. Cl. H01S 5/026; H01S 5/042; H01S 5/22; H01S 5/12

(52) U.S. Cl. CPC H01S 5/026; H01S 5/04256; H01S 2301/176; H01S 5/12; H01S 5/22

(57) ABSTRACT

A laser chip comprises a first lateral portion comprising a first metal stripe, a first lateral connector coupled to the first metal stripe, a second metal stripe, and a second lateral connector coupled to the second metal stripe; a second lateral portion coupled to the first lateral portion and comprising a first bonding pad coupled to the first lateral connector, and a second bonding pad coupled to the second lateral connector. A method of DFB laser chip fabrication, the method comprises depositing a first portion of a passivation layer; depositing a second metal stripe; depositing a second portion of the passivation layer; and depositing a first metal stripe.

### CROSS-REFERENCE TO RELATED APPLICATIONS

This is a continuation of Int'l Patent App. No. PCT/CN2019/089144 filed on May 30, 2019, which claims priority to U.S. Prov. Patent App. No. 62/678,091 filed on May 30, 2018 and U.S. Prov. Patent App. No. 62/821,082 filed on Mar. 20, 2019, all of which are incorporated by reference.

### TECHNICAL FIELD

The disclosed embodiments relate to laser chips in general and laser chip design in particular.

### BACKGROUND

Lasers have a wide variety of applications, including optical communications networks. One type of laser is a DFB laser. A DFB laser comprises an active region with a spatially-periodic grating. The grating comprises periodic changes in a refractive index, a gain, or a loss, which causes reflections in a cavity of the DFB laser. DFB lasers tend to be more stable than other laser types and provide clean single-mode operation. As a result, DFB lasers are favored in optical communications networks.

### SUMMARY

A first aspect relates to a laser chip comprising a first lateral portion comprising a first metal stripe, a first lateral connector coupled to the first metal stripe, a second metal stripe, and a second lateral connector coupled to the second metal stripe; and a second lateral portion coupled to the first lateral portion and comprising a first bonding pad coupled to the first lateral connector, and a second bonding pad coupled to the second lateral connector.

In a first implementation form of the laser chip according to the first aspect as such, the first metal stripe and the second metal stripe are longitudinally aligned.

In a second implementation form of the laser chip according to the first aspect as such or any preceding implementation form of the first aspect, the first bonding pad and the second bonding pad are laterally aligned.

In a third implementation form of the laser chip according to the first aspect as such or any preceding implementation form of the first aspect, the first lateral connector is wider than the second lateral connector.

In a fourth implementation form of the laser chip according to the first aspect as such or any preceding implementation form of the first aspect, the first metal stripe, the first lateral connector, and the first bonding pad extend substantially vertically to a top of the laser chip.

In a fifth implementation form of the laser chip according to the first aspect as such or any preceding implementation form of the first aspect, the second bonding pad extends substantially vertically to the top of the laser chip.

In a sixth implementation form of the laser chip according to the first aspect as such or any preceding implementation form of the first aspect, the second metal stripe and the second lateral connector do not extend substantially vertically to the top.

In a seventh implementation form of the laser chip according to the first aspect as such or any preceding implementation form of the first aspect, the first lateral portion further comprises a first waveguide coupled to the first metal stripe; and a second waveguide coupled to the second metal stripe.

In an eighth implementation form of the laser chip according to the first aspect as such or any preceding implementation form of the first aspect, the first waveguide and the second waveguide are ridge waveguides.

In a ninth implementation form of the laser chip according to the first aspect as such or any preceding implementation form of the first aspect, the first waveguide and the second waveguide are buried heterostructure waveguides.

In a tenth implementation form of the laser chip according to the first aspect as such or any preceding implementation form of the first aspect, the first waveguide comprises a first grating phase, wherein the second waveguide comprises a second grating phase, and wherein the second grating phase is shifted about 180° with respect to the first grating phase.

In an eleventh implementation form of the laser chip according to the first aspect as such or any preceding implementation form of the first aspect the laser chip further comprises a first waveguide that is an operative waveguide; and a second waveguide that is a non-operative waveguide.

A second aspect relates to a method of DFB laser chip fabrication, the method comprising: depositing a first portion of a passivation layer; depositing a second metal stripe; depositing a second portion of the passivation layer; and depositing a first metal stripe.

In a first implementation form of the method according to the second aspect as such, the method further comprises further depositing the first portion using PECVD; and further depositing the second portion using PECVD.

In a second implementation form of the method according to the second aspect as such or any preceding implementation form of the second aspect the method further comprises performing a first photolithography for the second metal stripe; and performing a second photolithography for the first metal stripe.

In a third implementation form of the method according to the second aspect as such or any preceding implementation form of the second aspect, the second metal stripe does not extend substantially vertically to a top of the DFB laser chip.

In a fourth implementation form of the method according to the second aspect as such or any preceding implementation form of the second aspect, the first metal stripe extends substantially vertically to the top of the DFB laser chip.

A third aspect relates to a method of DFB laser chip packaging, the method comprising obtaining a DFB laser chip comprising a first waveguide and a second waveguide, the first waveguide comprises a first grating phase, the second waveguide comprises a second grating phase, and the second grating phase is shifted about 180° with respect to the first grating phase; and testing the DFB laser chip to determine an operative waveguide, the operative waveguide is a waveguide with a higher SMSR.

In a first implementation form of the method according to the third aspect as such the method further comprises obtaining a fiber; and packaging the DFB laser chip by aligning the operative waveguide with the fiber.

In a second implementation form of the method according to the third aspect as such or any preceding implementation form of the third aspect the method further comprises blocking a non-operative waveguide, wherein the non-operative waveguide is a waveguide with a lower SMSR.

Any of the above embodiments may be combined with any of the other above embodiments to create a new embodiment. These and other features will be more clearly understood from the following detailed description taken in conjunction with the accompanying drawings and claims.

### BRIEF DESCRIPTION OF THE DRAWINGS

For a more complete understanding of this disclosure, reference is now made to the following brief description, taken in connection with the accompanying drawings and detailed description, wherein like reference numerals represent like parts.

FIG. 1 is a top view of a DFB laser chip according to an embodiment of the disclosure.

FIG. 2A is a cross-sectional view of the DFB laser chip taken along the 2A-2A line in FIG. 1 according to a first embodiment of the disclosure.

FIG. 2B is a cross-sectional view of the DFB laser chip taken along the 2B-2B line in FIG. 1 according to the first embodiment.

FIG. 3A is a cross-sectional view of the DFB laser chip taken along the 2A-2A line in FIG. 1 according to a second embodiment of the disclosure.

FIG. 3B is a cross-sectional view of the DFB laser chip taken along the 2B-2B line in FIG. 1 according to the second embodiment.

FIG. 4 is a flowchart illustrating a method of DFB laser chip fabrication according to an embodiment of the disclosure.

FIG. 5 is a graph of threshold gain difference versus grating phase at a back facet of a DFB laser chip.

FIG. 6 is a flowchart illustrating a method of DFB laser chip packaging according to an embodiment of the disclosure.

FIG. 7A is a schematic diagram of a laser driver circuit according to an embodiment of the disclosure.

FIG. 7B is a schematic diagram of a laser driver circuit according to another embodiment of the disclosure.

### DETAILED DESCRIPTION

It should be understood at the outset that, although an illustrative implementation of one or more embodiments are provided below, the disclosed systems and/or methods may be implemented using any number of techniques, whether currently known or in existence. The disclosure should in no way be limited to the illustrative implementations, drawings, and techniques illustrated below, including the exemplary designs and implementations illustrated and described herein, but may be modified within the scope of the appended claims along with their full scope of equivalents.

The following abbreviations apply:

dB: decibel(s)

DFB: distributed feedback laser

nm: nanometer(s)

PECVD: plasma-enhanced chemical vapor deposition

PON: passive optical network

SiNₓ: silicon nitride

SiO₂: silicon dioxide

SMSR: side-mode suppression ratio

SSMF: standard single-mode fiber

TO: transistor outline

μm: micrometer(s).

Manufacturers produce wafers comprising many DFB laser chips, or DFB laser dice, then cut the DFB laser chips from the wafers. For instance, a 2×2 inch wafer may comprise about 16,000 250×250 μm DFB laser chips. One measure of quality for DFB laser chips is an SMSR characteristic. A DFB laser chip's main spectral peak with the greatest optical power amplitude is called the main mode. The DFB laser chip's other spectral peaks with smaller optical power amplitudes are called side modes. The SMSR is a ratio of the greatest optical power amplitude of the main mode to an optical power amplitude of the largest side mode.

For PON applications, manufacturers typically use DFB laser chips with an SMSR of 35 dB or greater and discard the remaining DFB laser chips. The SMSRs of the DFB laser chips on a wafer can vary due to manufacturing process variations. For a 2×2 inch wafer comprising 16,000 DFB laser chips, only about 6,000-13,000 DFB laser chips will have an SMSR of 35 dB or greater and therefore be viable DFB laser chips. That represents a chip yield of about 40% to 80%.

There are two main ways to improve that chip yield. First, the manufacturer may improve the SMSRs of the DFB laser chips. Some approaches use two waveguides with associated cavities that have different lengths. The different lengths cause the cavities to have different phases and thus different SMSRs. However, the SMSRs may still not be optimal. Second, the manufacturer may reduce the size of the DFB laser chips. As mentioned above, some approaches use two waveguides. However, those waveguides may not be designed to optimize a DFB laser chip size. It is therefore desirable to manufacture DFB laser chips that overcome those obstacles and have improved SMSRs and smaller sizes.

Disclosed herein are embodiments for laser chip design. First, the embodiments provide for DFB laser chips with two waveguides. The DFB laser chips may therefore be referred to as dual-waveguide DFB laser chips, dual-waveguide laser chips, or dual-waveguide lasers. The two waveguides have grating phases that are shifted about 180° with respect to each other. The grating phase shift guarantees that at least one waveguide, an operative waveguide, has an acceptable SMSR. During packaging, a packager ensures that the operative waveguide is used. The guarantee of an operative waveguide increases a chip yield from about 40%-80% to about 100%. Second, to reduce a size of the DFB laser chips, first lateral portions of the DFB laser chips comprise metal stripes and lateral connectors for the waveguides, and second lateral portions of the DFB laser chips comprise bonding pads for the waveguides. A fabrication method comprises separate metal deposition steps for a first metal stripe and a second metal stripe. Compared to other DFB laser chips with two waveguides, the disclosed DFB laser chips have an about 30% smaller area. By guaranteeing an operative waveguide and reducing the area of the DFB laser chips, the disclosed embodiments increase a chip yield for a 2×2 inch wafer from about 6,000-13,000 DFB laser chips to about 22,000 DFB laser chips.

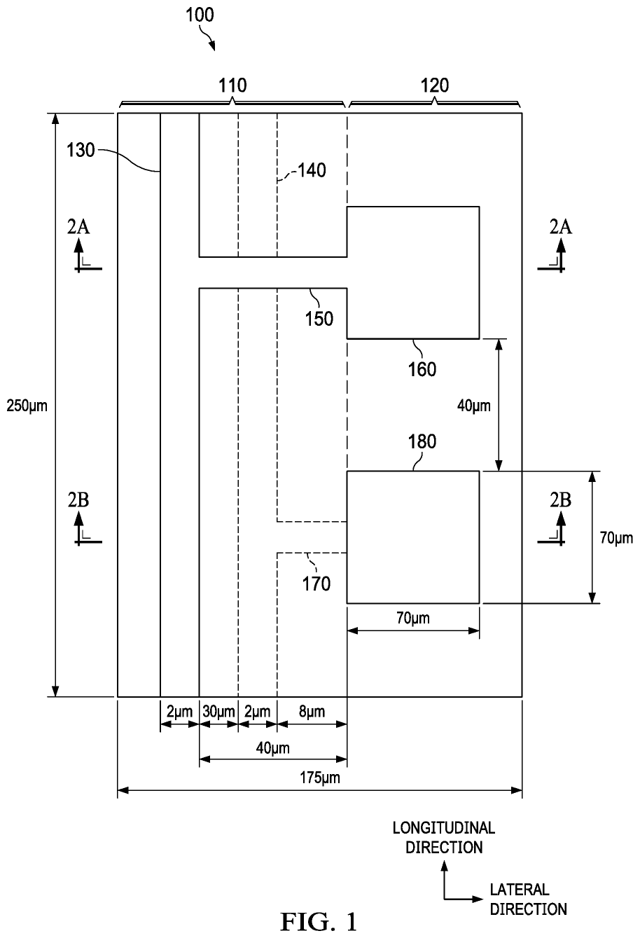

FIG. 1 is a top view of a DFB laser chip 100 according to an embodiment of the disclosure. FIG. 1 shows a lateral direction and a longitudinal direction, which are orthogonal to each other. The DFB laser chip 100 may be referred to as a laser chip, as a laser die, or simply as a chip or a die. The DFB laser chip 100 may have a length of about 250 μm and a width of about 175 μm. The DFB laser chip 100 is generally divided into a first lateral portion 110 and a second lateral portion 120.

The first lateral portion 110 extends longitudinally down a length of the DFB laser chip 100. The first lateral portion 110 comprises a first metal stripe 130, a second metal stripe 140, a first lateral connector 150, and a second lateral connector 170. The first metal stripe 130, the second metal stripe 140, the first lateral connector 150, and the second lateral connector 170 may comprise gold, titanium, platinum, or other suitable electrically-conductive material or alloy. The first metal stripe 130 and the second metal stripe 140 may be longitudinally aligned, separated by a width of about 30 μm, have a length of about 250 μm, and may have a width of about 2 μm in some examples. The first lateral connector 150 is wider than the second lateral connector 170. Specifically, the first lateral connector 150 may have a width of about 40 μm, and the second lateral connector 170 may have a width of about 8 μm in some examples.

The second lateral portion 120 is coupled to the first lateral portion 110. The second lateral portion 120 extends longitudinally down the length of the DFB laser chip 100. The second lateral portion 120 comprises a first bonding pad 160 and a second bonding pad 180. The first bonding pad 160 and the second bonding pad 180 may comprise gold, titanium, platinum, or other suitable electrically-conductive material or alloy. The first bonding pad 160 and the second bonding pad 180 may be laterally aligned, may be separated by a length of about 40 μm, may have a length of about 70 μm, and may have a width of about 70 μm in some examples.

The second metal stripe 140 and the second lateral connector 170 are shown in dashed lines to indicate that they do not extend substantially vertically to a top of the DFB laser chip 100. The second metal stripe 140 and the second lateral connector 170 are not externally visible in the top view. However, the second bonding pad 180 is shown in solid, continuous lines to indicate that it does extend substantially vertically to the top of the DFB laser chip 100. Likewise, the first metal stripe 130, the first lateral connector 150, and the first bonding pad 160 are shown in solid, continuous lines to indicate that they do extend substantially vertically to the top of the DFB laser chip 100. The first metal stripe 130, the first lateral connector 150, and the first bonding pad 160 are externally visible in the top view.

As can be seen, the DFB laser chip 100 is not drawn to scale in some places in order to deemphasize some features and emphasize other features. For instance, the first metal stripe 130 and the second metal stripe 140 may be separated by a width of about 30 μm and have a width of about 2 μm. However, FIG. 1 deemphasizes the former width and emphasizes the latter width.

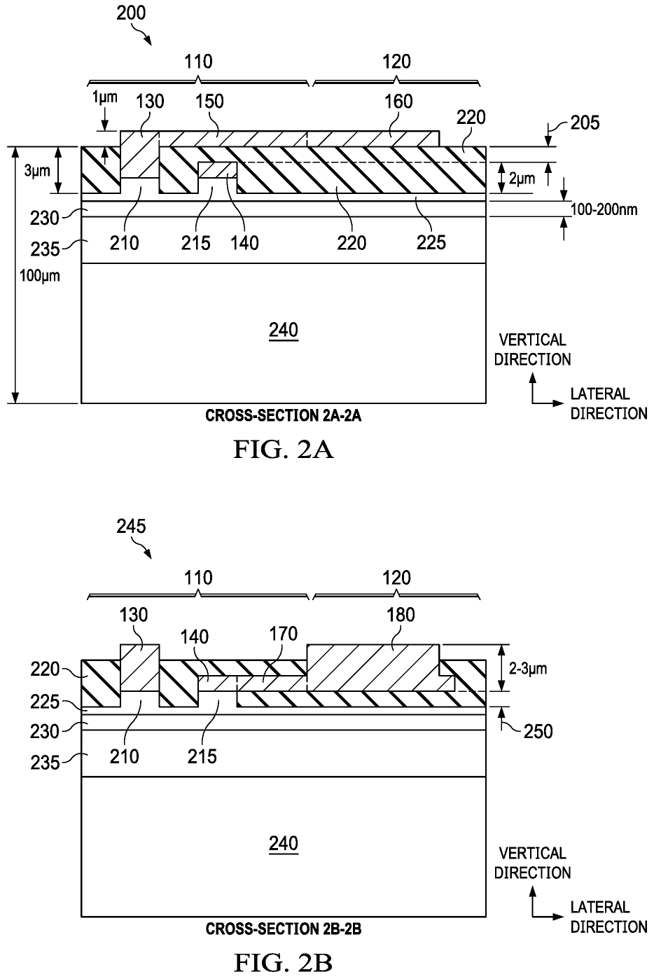

FIG. 2A is a cross-sectional view 200 of the DFB laser chip 100 taken along the 2A-2A line in FIG. 1 according to a first embodiment of the disclosure. FIG. 2A shows the lateral direction and a vertical direction, which are orthogonal to each other. Thus, the vertical direction is also orthogonal to the longitudinal direction in FIG. 1. The cross-sectional view 200 shows that the DFB laser chip 100 comprises the first lateral portion 110, the second lateral portion 120, the first metal stripe 130, the first lateral connector 150, the first bonding pad 160, and the second metal stripe 140 in FIG. 1. The first lateral portion 110 and the second lateral portion 120 extend substantially vertically down a height of the DFB laser chip 100. The first lateral connector 150 and the first bonding pad 160 may have a height of about 1 μm. The cross-sectional view 200 further shows that the DFB laser chip 100 may have a height of about 100 m.

The cross-sectional view 200 further shows that the DFB laser chip 100 comprises a first vertical gap 205, a first waveguide 210, a second waveguide 215, a passivation layer 220, a waveguide base 225, an active layer 230, an epitaxial layer 235, and a substrate 240. The first vertical gap 205 is part of the passivation layer 220, separates the first lateral connector 150 from the second metal stripe 140, and may have a height of about 1 μm in some examples. The first waveguide 210 comprises a first ridge (or projection) extending substantially vertically above the waveguide base 225, and the first waveguide 210 comprises at least some of the waveguide base 225 extending vertically below the first ridge. Likewise, the second waveguide 215 comprises a second ridge (or projection) extending substantially vertically above the waveguide base 225, and the second waveguide 215 comprises at least some of the waveguide base 225 extending vertically below the second ridge. The first waveguide 210 and the second waveguide 215 may therefore be referred to as ridge waveguides. Thus, the DFB laser chip 100 may be referred to as a dual-ridge waveguide DFB laser chip. Together, the second metal stripe 140 and the second ridge may have a combined height of about 2 μm. The passivation layer 220 may comprise SiNₓ or SiO₂ and may have a height of about 3 μm. The active layer 230 may have a height of about 100-200 nm in some examples.

FIG. 2B is a cross-sectional view 245 of the DFB laser chip 100 taken along the 2B-2B line in FIG. 1 according to the first embodiment. FIG. 2B shows the lateral direction and the vertical direction. The cross-sectional view 245 shows that the DFB laser chip 100 comprises the first lateral portion 110, the second lateral portion 120, the first metal stripe 130, the second metal stripe 140, the second lateral connector 170, and the second bonding pad 180 in FIG. 1. The second bonding pad 180 may have a height of about 2-3 μm in some examples.

The cross-sectional view 245 further shows that the DFB laser chip 100 comprises the first waveguide 210, the second waveguide 215, the passivation layer 220, the waveguide base 225, the active layer 230, the epitaxial layer 235, and the substrate 240 in FIG. 2A. The cross-sectional view 245 further shows that the DFB laser chip 100 comprises a second vertical gap 250. The second vertical gap 250 is part of the passivation layer 220, separates the second bonding pad 180 from the waveguide base 225, and may have a height of about 1 μm in some examples.

In operation, an external driving current is injected into the first bonding pad 160, travels through the first lateral connector 150 and the first metal stripe 130, and enters the active layer 230. The external driving current causes a population inversion in the active layer 230, which causes the active layer 230 to provide an optical gain. A population inversion occurs when more electrons are in a higher energy state than in a lower energy state. An optical wave travels back and forth inside the first waveguide 210 and is amplified by the active layer 230. If the optical gain is higher than a cavity loss, an optical power builds up and lasing starts. In addition, a grating layer, either above or below the active layers 230, forms a wavelength-selective filter so that only a specific wavelength satisfying a lasing condition can lase. Controlling the external driving current controls an output power of the DFB laser chip 100. While the operation is discussed with respect to the first bonding pad 160, the first lateral connector 150, the first metal stripe 130, and a first cavity comprising the waveguide 210 and corresponding first facets, the same operation occurs for the second bonding pad 180, the second lateral connector 170, the second metal stripe 140, and a second cavity comprising the waveguide 215 and corresponding second facets.

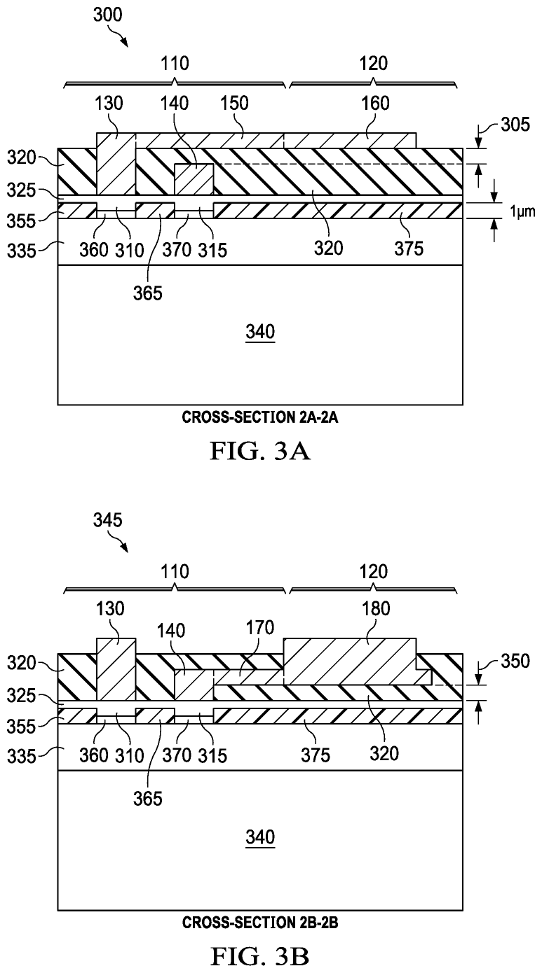

FIG. 3A is a cross-sectional view 300 of the DFB laser chip 100 taken along the 2A-2A line in FIG. 1 according to a second embodiment of the disclosure. The cross-sectional view 300 is similar to the cross-sectional view 200 in FIG. 2A. Specifically, like the cross-sectional view 200, the cross-sectional view 300 shows that the DFB laser chip 100 comprises the first lateral portion 110, the second lateral portion 120, the first metal stripe 130, the first lateral connector 150, the first bonding pad 160, and the second metal stripe 140 in FIG. 1. In addition, the cross-sectional view 300 shows that the DFB laser chip 100 further comprises a first vertical gap 305, a first waveguide 310, a second waveguide 315, a passivation layer 320, a waveguide base 325, an epitaxial layer 335, and a substrate 340, which are similar to the first vertical gap 205, the first waveguide 210, the second waveguide 215, the passivation layer 220, the waveguide base 225, the epitaxial layer 235, and the substrate 240, respectively, in the cross-sectional view 200.

However, unlike in the cross-sectional view 200 in which the second metal stripe 140 and the second waveguide 215 may have a combined height of about 1 μm, in the cross-sectional view 300, the second metal stripe 140 alone has a height of about 1 μm. In addition, unlike the cross-sectional view 200, which shows one active layer 230, the cross-sectional view 300 shows a first active layer 360 and a second active layer 370. In addition, unlike the cross-sectional view 200, the cross-sectional view 300 shows current-blocker layers 355, 365, 375. The first waveguide 310 and the second waveguide 315 extend below the waveguide base 325 in a vertical direction; are buried between the current-blocker layers 355, 365, 375; and may therefore be referred to as buried heterostructure waveguides 310 and 315. Thus, the DFB laser chip 100 may be referred to as a buried heterostructure waveguide DFB laser chip. The current-blocker layers 355, 365, 375 may have a height of about 1 μm in some examples.

FIG. 3B is a cross-sectional view 345 of the DFB laser chip 100 taken along the 2B-2B line in FIG. 1 according to the second embodiment. The cross-sectional view 345 is similar to the cross-sectional view 245 of FIG. 2B. Specifically, like the cross-sectional view 245, the cross-sectional view 345 shows that the DFB laser chip 100 comprises the first lateral portion 110, the second lateral portion 120, the first metal stripe 130, the second metal stripe 140, the second lateral connector 170, and the second bonding pad 180 in FIG. 1. In addition, the cross-sectional view 345 shows that the DFB laser chip 100 further comprises the first waveguide 310, the second waveguide 315, the passivation layer 320, the waveguide base 325, a second vertical gap 350, the epitaxial layer 335, and the substrate 340, which are similar to the first waveguide 210, the second waveguide 215, the passivation layer 220, the waveguide base 225, the second vertical gap 250, the epitaxial layer 235, and the substrate 240, respectively, in the cross-sectional view 245. However, unlike the cross-sectional view 245, the cross-sectional view 345 shows the current-blocker layers 355, 365, 375; the first active layer 360; and the second active layer 370.

As shown, the DFB laser chip 100 has two waveguides, either the first waveguide 210 and the second waveguide 215 on one hand or the first waveguide 310 and the second waveguide 315 on the other hand. Unlike other DFB laser chips with two waveguides, the DFB laser chip 100 has the first metal stripe 130, the second metal stripe 140, the first lateral connector 150, and the second lateral connector 170 in the first lateral portion 110 and has the first bonding pad 160 and the second bonding pad 180 in the second lateral portion 120. In addition, unlike the other DFB laser chips with two waveguides, the DFB laser chip 100 has the first waveguides 210, 310 and the second waveguides 215, 315 in the first lateral portion 110 and has the first bonding pad 160 and the second bonding pad 180 in the second lateral portion 120. Compared to those other DFB laser chips, the DFB laser chip 100 therefore has an about 30% smaller area.

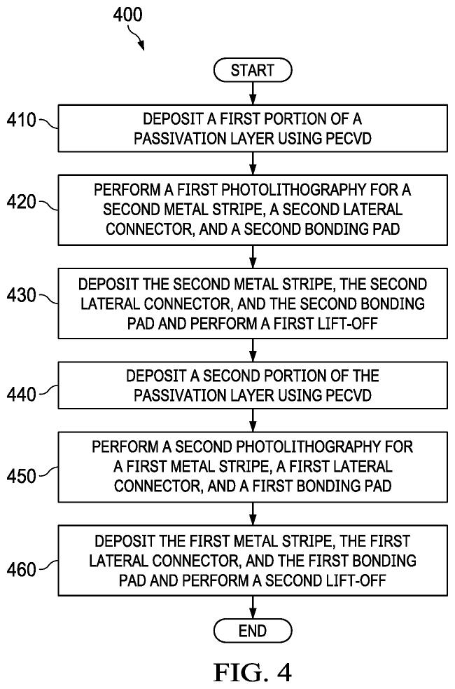

FIG. 4 is a flowchart illustrating a method 400 of DFB laser chip fabrication according to an embodiment of the disclosure. The method 400 is part of an overall fabrication of the DFB laser chip 100. A manufacturer may perform the method 400 and the overall fabrication for multiple DFB laser chips on a wafer at the same time. For instance, the wafer is a 2×2 inch wafer comprising 22,000 DFB laser chips.

At step 410, a first portion of a passivation layer is deposited using PECVD. For instance, a manufacturer deposits the passivation layer 220 up to a height of the second metal stripe 140 and the second lateral connector 170. Alternatively, another deposition process is used. At step 420, a first photolithography is performed for a second metal stripe, a second lateral connector, and a second bonding pad. For instance, the manufacturer performs photolithography for the second metal stripe 140, the second lateral connector 170, and the second bonding pad 180. At step 430, the second metal stripe, the second lateral connector, and the second bonding pad are deposited and a first lift-off is performed. For instance, the manufacturer deposits the second metal stripe 140, the second lateral connector 170, and the second bonding pad 180, and the manufacturer lifts off any stencil left from the first photolithography in step 420.

At step 440, a second portion of a passivation layer is deposited using PECVD. For instance, a manufacturer deposits the remaining portion of the passivation layer 220. Alternatively, another deposition process is used. At step 450, a second photolithography is performed for a first metal stripe, a first lateral connector, and a first bonding pad. For instance, the manufacturer performs photolithography for the first metal stripe 130, the first lateral connector 150, and the first bonding pad 160. Finally, at step 460, the first metal stripe, the first lateral connector, and the first bonding pad are deposited and a second lift-off is performed. For instance, the manufacturer deposits the first metal stripe 130, the first lateral connector 150, and the first bonding pad 160, and the manufacturer lifts off any stencil left from the second photolithography in step 450.

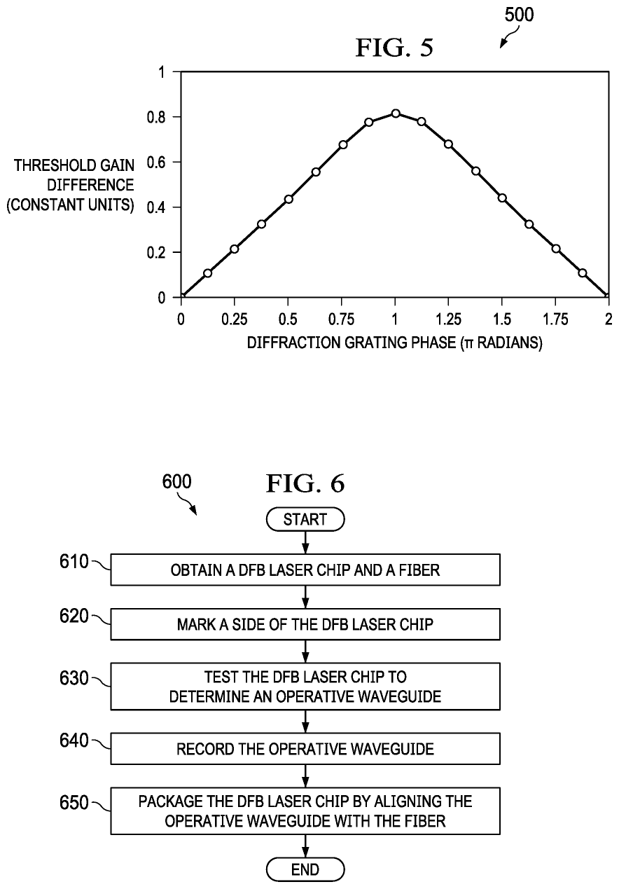

FIG. 5 is a graph 500 of threshold gain difference versus grating phase at a back facet of a DFB laser chip. The back facet may be a back surface, face, or mirror layer. In the graph 500, the x-axis represents a grating phase in π radians, and the y-axis represents a threshold gain difference in constant units. The threshold gain difference is between a main mode and a side mode and therefore correlates to an SMSR. As shown, as the grating phase increases from 0π radians to 1π radians, the threshold gain difference increases from 0 to a peak of about 0.8; as the grating phase increases from 1π radians to 2π radians, the threshold gain difference decreases from the peak of 0.8 to 0. A threshold gain difference of 0.4 correlates to an SMSR of 35 dB and therefore represents a waveguide with an acceptable grating phase. The threshold gain difference of 0.4 corresponds to a diffraction grating phase of 0.46π radians and 1.54π radians. Thus, a grating phase of 0π-0.46π radians and 1.54π-2π radians may be unacceptable, while a grating phase of 0.46π-1.54π radians may be acceptable.

Returning to FIGS. 2A-3B, the first waveguides 210, 310 and the second waveguides 215, 315 each comprise a grating phase. The grating phases vary due to manufacturing process variations, so it may be difficult to ensure that the first waveguides 210, 310 and the second waveguides 215, 315 comprise grating phases in the range of 0.46π-1.54π radians. While that may be difficult, manufacturing processes allow for less variation in grating phase shifts between those grating phases.

Specifically, a manufacturer may make the first waveguide 210 and the second waveguide 215 have grating phases shifted by about 1π radians, or about 180°, with respect to each other. Similarly, the manufacturer may make the first waveguide 310 and the second waveguide 315 have grating phases shifted by about 180° with respect to each other. The manufacturer may do so by making gratings of the first waveguides 210, 310 have high refractive index points where gratings of the second waveguides 215, 315 have low refractive index points and by making the gratings of the first waveguides 210, 310 have low refractive index points where the gratings of the second waveguides 215, 315 have high refractive index points. Alternatively, the grating phases are shifted by another suitable amount. Alternatively, the DFB laser chip 100 comprises N waveguides that have grating phases shifted by about 2π/N radians, or about 360°/N, with respect to each other.

In a first example, a grating phase of the first waveguide 210 is 0.25π radians, which is outside the range of 0.46π-1.54π radians. However, if the manufacturer makes the first waveguide 210 and the second waveguide 215 have grating phases shifted by 180° with respect to each other, then a grating phase of the second waveguide 215 is 1.25π radians, which is inside the range of 0.46π-1.54π radians. In a second example, a grating phase of the first waveguide 210 is 1.25π radians, which is inside the range of 0.46π-1.54π radians. However, if the manufacturer makes the first waveguide 210 and the second waveguide 215 have grating phases shifted by 180° with respect to each other, then a grating phase of the second waveguide 215 is 0.25π radians, which is outside the range of 0.46π-1.54π radians.

In both the first example and the second example, either the first waveguide 210 or the second waveguide 215 has a grating phase inside the range the range of 0.46π-1.54π radians. The same will hold true for any two waveguides with grating phases that are shifted 180° with respect to each other. As a result, a wafer with a plurality of the DFB laser chips 100 may have a chip yield of about 100%. Combining that improvement with the about 30% reduction in area, the DFB laser chip 100 may increase a chip yield for a 2×2 inch wafer from about 6,000-13,000 DFB laser chips to about 22,000 DFB laser chips.

FIG. 6 is a flowchart illustrating a method 600 of DFB laser chip packaging according to an embodiment of the disclosure. At step 610, a DFB laser chip and a fiber are obtained. For instance, the DFB laser chip is the DFB laser chip 100, and the fiber is an SSMF.

At step 620, a side of the DFB laser chip is marked. For instance, a manufacturer marks a top longitudinal side or a bottom longitudinal side of a DFB laser chip like the DFB laser chip 100 in FIG. 1. The top longitudinal side or the bottom longitudinal side may correspond to an inactive side of the DFB laser chip 100 that does not emit light waves. The marking provides an orientation of the DFB laser chip 100 for subsequent steps of the method 600.

At step 630, the DFB laser chip is tested to determine an operative (or most suitable) waveguide. For instance, the manufacturer tests light waves emitted from the first waveguide 210 and the second waveguide 215 to determine SMSRs of the first waveguide 210 and the second waveguide 215. The packager determines that a waveguide with a higher SMSR is the operative waveguide. The higher SMSR is equal to or greater than about 35 dB. A waveguide with a lower SMSR is a non-operative waveguide. The lower SMSR is less than about 35 dB.

At step 640, the operative waveguide is recorded. For instance, the manufacturer records which side of the DFB laser chip 100 is marked and whether a left waveguide or a right waveguide is operative. That information is sufficient to subsequently determine whether the first waveguide 210 or the second waveguide 215 is the operative waveguide. Optionally, the manufacturer marks the operative waveguide, marks the non-operative waveguide, or blocks off the non-operative waveguide.

Finally, at step 650, the DFB laser chip is packaged by aligning the operative waveguide with the fiber. For instance, a packager determines which waveguide is the operative waveguide based on the marking in step 620 and the recording in step 640. The packager then aligns the operative waveguide with the fiber and secures the fiber to the DFB laser chip 100. The fiber may be part of a larger component that secures to the DFB laser chip 100.

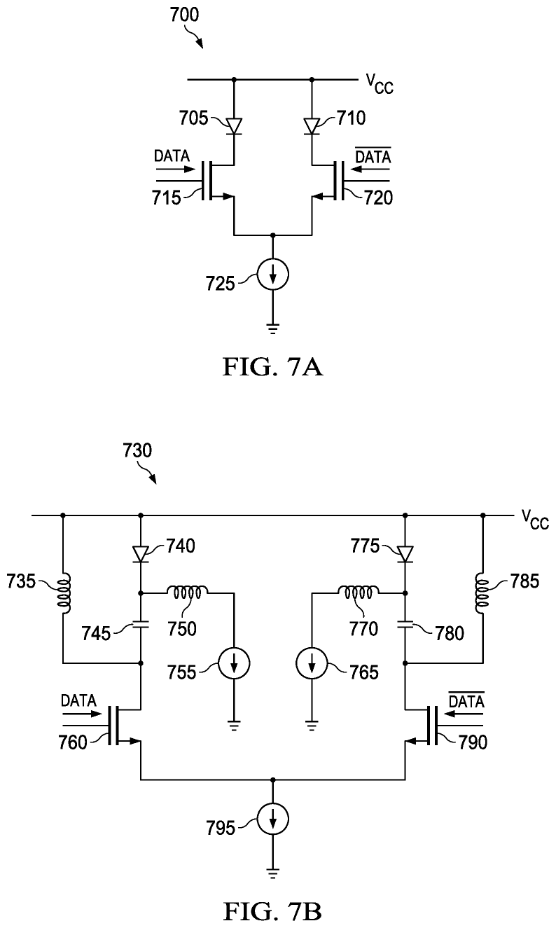

FIG. 7A is a schematic diagram of a laser driver circuit 700 according to an embodiment of the disclosure. The laser driver circuit 700 comprises lasers (or laser light-emitting diodes) 705, 710; transistors 715, 720; and a current source 725. The lasers 705, 710 may correspond to the first waveguides 210, 310 or the second waveguides 215, 315 in the DFB laser chip 100. The current source 725 provides a bias to the lasers 705, 710.

FIG. 7B is a schematic diagram of a laser driver circuit 730 according to another embodiment of the disclosure. The laser driver circuit 730 comprises inductors 735, 750, 770, 785; lasers 740, 775; capacitors 745, 780; current sources 755, 765, 795; and transistors 760, 790. The lasers 740, 775 may correspond to the first waveguides 210, 310 or the second waveguides 215, 315 in the DFB laser chip 100. The current sources 755, 765, 795 provide biases to the lasers 740, 775.

The laser driver circuits 700, 730 provide at least three advantages. First, the lasers 705, 710 and 740, 775 provide matched loads. Second, the DFB laser chip 100 provides constant heat, so the laser driver circuits 700, 730 do not experience wavelength drift when operating in a burst mode. Third, when the DFB laser chip 100 and photodetectors are in the same package, for instance the same TO can, for single-fiber bidirectional transmission, crosstalk from a transmitter to a receiver is reduced because a differential signal is applied to the lasers 705, 710 and 740, 775.

The term “about” means a range including ±10% of the subsequent number unless otherwise stated. The term “substantially” means within 1%, 5%, 10%, or another suitable metric or means within manufacturing tolerances. While several embodiments have been provided in the present disclosure, it may be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various embodiments as discrete or separate may be combined or integrated with other systems, components, techniques, or methods without departing from the scope of the present disclosure. Other items shown or discussed as coupled may be directly coupled or may be indirectly coupled or communicating through some interface, device, or intermediate component whether electrically, mechanically, or otherwise. Other examples of changes, substitutions, and alterations are ascertainable by one skilled in the art and may be made without departing from the spirit and scope disclosed herein.

What is claimed is:

1. A laser chip, comprising:
a substrate including a top surface;
a first conductive trace extending substantially longitudinally on the top surface of the substrate, the first conductive trace comprising:
a first lateral connector coupled to the first conductive trace at a first end and extending substantially laterally on the top surface from the first conductive trace; and
a first bonding pad formed on the top surface and on a second end of the first lateral connector, the first bonding pad located a first distance from the first conductive trace; and
a second conductive trace extending substantially longitudinally within the substrate, the second conductive trace being substantially parallel to the first conductive trace, and at least a portion of the second conductive trace is beneath the top surface, the second conductive trace comprising:
a second lateral connector coupled to the second conductive trace at a first end and extending substantially laterally from the second conductive trace, the second lateral connector having a second end extending to the top surface of the substrate; and
a second bonding pad formed on a second end of the second lateral connector on the top surface of the substrate, the second bonding pad located the first distance from the first conductive trace;
the first lateral connector of the first conductive trace being electrically isolated from the second conductive trace.

2. The laser chip of claim 1, wherein the first lateral connector is separated from the second conductive trace by a passivation layer.

3. The laser chip of claim 1, wherein at least a longitudinal portion of the second conductive trace is below the top surface of the substrate and the second bonding pad is exposed at the top surface of the substrate.

4. The laser chip of claim 1, wherein the first bonding pad and the second bonding pad are substantially longitudinally aligned and the first bonding pad and the second bonding pad are substantially equidistant from the first conductive trace.

5. The laser chip of claim 1, wherein the first conductive trace, the first lateral connector, and the first bonding pad are exposed at the top surface of the substrate, while the at least a portion of the second conductive trace is beneath the top surface.

6. The laser chip of claim 1, wherein the first lateral connector and the second lateral connector comprise ridge waveguides.

7. The laser chip of claim 1, wherein the first lateral connector and the second lateral connector comprise buried heterostructure waveguides.

8. The laser chip of claim 1, wherein the first lateral connector comprises a first waveguide including a first grating phase, the second lateral connector comprises a second waveguide including a second grating phase, and the second grating phase is shifted about 180° with respect to the first grating phase.

9. A method of distributed feedback (DFB) laser chip fabrication, the method comprising:
depositing a first portion of a passivation layer on a substrate;
depositing a second conductive trace and a second lateral connector on the first portion of the passivation layer, the second conductive trace extending substantially longitudinally with respect to the substrate, the second lateral connector coupled to the second conductive trace and extending substantially laterally with respect to the substrate;
depositing a second portion of the passivation layer, the second portion covering at least part of the second conductive trace and forming a top surface of the substrate; and
depositing a first conductive trace, a first lateral connector, a first bonding pad, and a second bonding pad on the second portion of the passivation layer, the first conductive trace extending substantially longitudinally with respect to the substrate, the first lateral connector coupled to the first conductive trace at a first end and extending substantially laterally from the first conductive trace, the first bonding pad coupled to a second end of the first lateral connector, the first bonding pad located a first distance from the first conductive trace, the second bonding pad coupled to the second lateral connector, the second bonding pad exposed at the top surface.

10. The method of claim 9, further comprising:
further depositing the first portion of the passivation layer using plasma-enhanced chemical vapor deposition (PECVD); and
further depositing the second portion of the passivation layer using PECVD.

11. The method of claim 9, further comprising:
performing a first photolithography for the second conductive trace; and
performing a second photolithography for the first conductive trace.

12. The method of claim 9, wherein the first lateral connector is separated from the second conductive trace by the second portion of the passivation layer.

13. The method of claim 9, wherein at least a longitudinal portion of the second conductive trace is below a top surface of the substrate and the second bonding pad is exposed at the top surface of the substrate.

14. The method of claim 9, wherein the first bonding pad and the second bonding pad are substantially longitudinally aligned and the first bonding pad and the second bonding pad are substantially equidistant from the first conductive trace.

15. The method of claim 9, wherein the first conductive trace, the first lateral connector, and the first bonding pad are exposed at the top surface of the substrate, while at least a longitudinal portion of the second conductive trace is beneath the second portion of the passivation layer.

16. The method of claim 9, wherein the first lateral connector and the second lateral connector comprise ridge waveguides.

17. The method of claim 9, wherein the first lateral connector and the second lateral connector comprise buried heterostructure waveguides.

18. The method of claim 9, wherein the first lateral connector comprises a first waveguide including a first grating phase, the second lateral connector comprises a second waveguide including a second grating phase, and the second grating phase is shifted about 180° with respect to the first grating phase.

19. A method of distributed feedback (DFB) laser chip packaging, the method comprising:
obtaining a DFB laser chip comprising a first waveguide and a second waveguide, the first waveguide comprises a first grating phase, the second waveguide comprises a second grating phase, and the second grating phase is shifted about 180° with respect to the first grating phase; and
testing the DFB laser chip to determine an operative waveguide, the operative waveguide comprising a higher side-mode suppression ratio (SMSR).

20. The method of claim 19, further comprising:
obtaining a fiber; and
packaging the DFB laser chip by aligning the operative waveguide with the fiber.

21. The method of claim 20, further comprising blocking a non-operative waveguide, the non-operative waveguide comprising a lower SMSR.
